(19) United States
(12) Patent Application Publication
(10) Pub. No.: US 2011/0234282 A1
(43) Pub. Date: Sep. 29, 2011

(54) Method And Circuit For Testing And Characterizing High Speed Signals Using An ON-Chip Oscilloscope

(75) Inventor: Rajesh Chopra, Pleasanton, CA (US)

(73) Assignee: MoSys, Inc., Santa Clara, CA (US)

(21) Appl. No.: 13/048,770

(22) Filed: Mar. 15, 2011

Related U.S. Application Data
(60) Provisional application No. 61/316,807, filed on Mar. 23, 2010.

(51) Int. Cl. H03K 3/00

(52) U.S. Cl. 327/199

(57) ABSTRACT

A method and structure for characterizing signals used to operate high speed circuitry on an integrated circuit chip. Signals to be characterized, such as column select signals, sense amplifier enable signals and word line signals, are generated on the chip. Each of these signals has an identical corresponding pattern during successive cycles of an input clock signal. These signals are sampled on the chip with successively delayed versions of the input clock signal, thereby generating a plurality of data samples that represent the patterns of the signals over a cycle of the input clock signal. The data samples are stored in a memory block on the chip, and are subsequently serialized and transferred to a location external to the chip.

### RELATED APPLICATIONS

This application claims priority from U.S. Provisional Patent Application 61/316,807, entitled “Method And Circuit For Testing And Characterizing High Speed Signals Using An ON-Chip Oscillator”, which was filed on Mar. 23, 2010, and is incorporated by reference herein.

### FIELD OF THE INVENTION

The present invention is directed to an on-chip oscilloscope for testing periodic signals at different nodes of a high speed circuit. The high-speed circuit can be in a random access memory (RAM), a non-volatile memory (NVM), a central processing unit (CPU) or any other similar device. The invention is applicable to any type of high-speed circuit that must be characterized in order to adjust the timing of the electronic signals.

### RELATED ART

An on-chip testing system is shown in U.S. Pat. No. 7,096,144, to Bateman. However, the on-chip testing system of Bateman cannot debug high speed circuits. The prior art tests signals at a slow frequency due to its use of pads whenever the signals switch. The strobe signal is provided by an external tester and thus is unable to handle testing at high frequencies. In addition, the external tester requires programming, which prevents use in a system-on-a-chip (SoC) environment. It would therefore be desirable to have a method and circuit for testing and characterizing high speed signals on an integrated circuit that overcomes the deficiencies of conventional on-chip testing systems.

### SUMMARY

Accordingly, the present invention provides a method and structure for characterizing internal signals used to operate high speed circuitry on an integrated circuit chip. The internal signals to be characterized, such as column select signals, sense amplifier enable signals and word line signals, are generated on the chip. These internal signals are generated such that each of these signals has an identical corresponding pattern during successive cycles of an input clock signal. These generated internal signals are sampled on the chip with successively delayed versions of the input clock signal, thereby generating a plurality of data samples that represent the patterns of the generated internal signals over a cycle of the input clock signal. The data samples are stored in a memory block on the chip, and are subsequently serialized and transferred to a location external to the chip, where these data samples can be analyzed to identify signal characteristics, such as signal-to-signal delay and signal slew rate.

In accordance with one embodiment, the successively delayed versions of the input clock signal are generated by applying the input clock signal to a plurality of series-connected delay elements. Each of the delay elements introduces a known fixed delay to the input clock signal.

In accordance with another embodiment, the data samples are acquired by latching the generated internal signals into flip-flops in response to the successively delayed versions of the input clock signal. A generated internal signal can be applied to two flip-flops having two different trip points to identify the slew rate of the generated internal signal.

The present invention will be more fully understood in view of the following description and drawings.

### BRIEF DESCRIPTION OF THE DRAWINGS

FIG. 1 is a circuit diagram of an on-chip oscilloscope circuit used to debug and characterize high-speed circuitry located on the same chip, in accordance with one embodiment of the present invention.

FIG. 2, which includes FIGS. 2A, 2B, 2C, 2D and 2E, is a waveform diagram illustrating 18 test cycles, which are used to evaluate the internal signals CLK, A, B and C, in accordance with one embodiment of the present invention.

FIG. 3 is a table that illustrates the data sample values and corresponding addresses that are associated with the 18 test cycles of FIG. 2, in accordance with one embodiment of the present invention.

FIG. 4 is a waveform diagram that illustrates digital signals that are derived from the data sample values of the table of FIG. 3 in accordance with one embodiment of the present invention.

### DETAILED DESCRIPTION

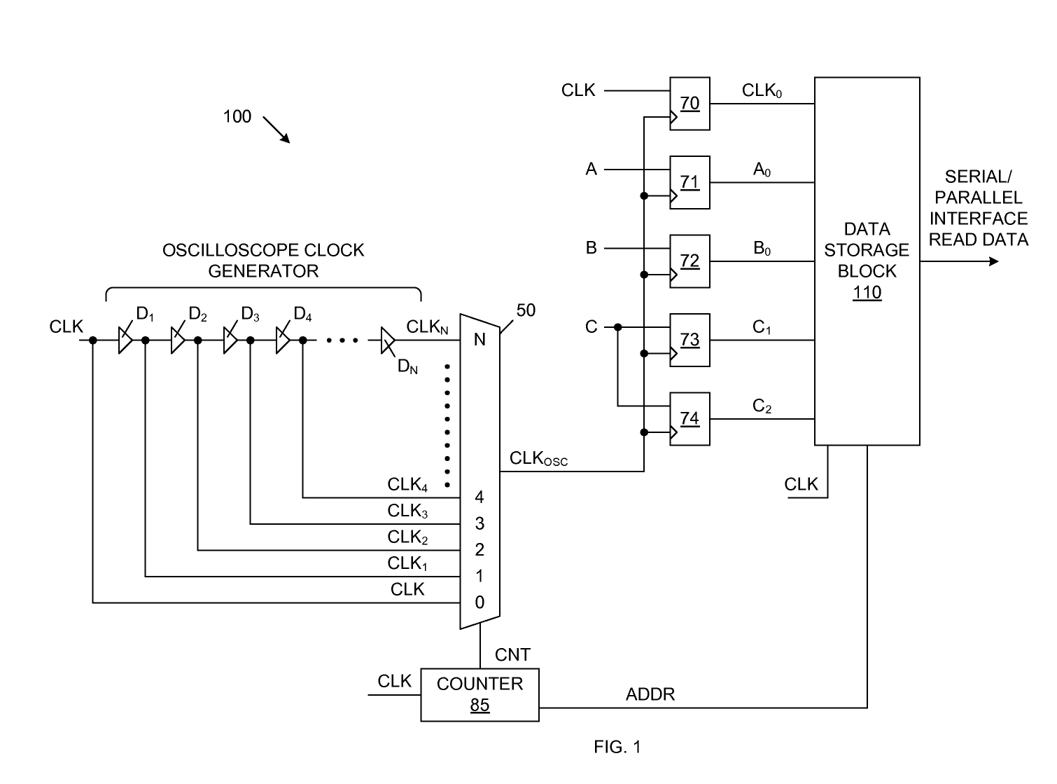

FIG. 1 is a circuit diagram of an on-chip oscilloscope circuit 100 that may be used to debug and characterize high-speed circuitry located on the same integrated circuit chip, in accordance with one embodiment of the present invention. On-chip oscilloscope circuit 100 includes N delay circuits D₁-D_{N}, multiplexer 50, flip-flops 70-74, counter circuitry 85, and data storage block 110. The delay circuits D₁-D_{N} form an oscilloscope clock generator, which generates a plurality of N test clock signals in response to an input clock signal, CLK. Each delay circuit D_{X} (X=1 to N) introduces a delay D to the received signal. Thus, each delay circuit D_{X} provides a corresponding output clock signal (CLK_{X}), which is identical to the input clock signal CLK, but is delayed by a time period of X*D. For example, the clock signal CLK4 is delayed by 4*D with respect to the input clock signal CLK. In one embodiment, the delay D is equal to about 10 picoseconds (ps) or more. However, it is understood that the delay D can be selected to have other values in other embodiments. The delay D is selected in view of the required granularity of a particular application, in a manner that will be clear in view of the following description.

In accordance with one embodiment, the number of delay circuits N is selected such that the delay N*D introduced to create the clock signal CLK_{N} is equal to the period of the input clock signal CLK, minus one delay period D. As a result, the rising edges of the clock signals CLK₁-CLK_{N} span the entire period of the input clock signal CLK.

The input clock signal CLK and the delayed clock signals CLK₁-CLK_{N} are provided to inputs of multiplexer 50. Multiplexer 50 is controlled to route one of these clock signals as a test clock signal CLK_{OSC}, in response to a count value CNT provided by counter circuitry 85. The counter circuitry 85 increments the counter value CNT in response to the input clock signal CLK, in a manner described in more detail below. In general, the input clock signal CLK increments the count value CNT in response to each rising edge of the input clock signal CLK, such that the clocks signals CLK₁-CLK_{N} are sequentially routed through the multiplexer 50 during successive cycles of the input clock signal CLK to create the test clock signal CLK_{OSC}.

The test clock signal CLK_{OSC} is provided to clock input terminals of flip-flops 70-74. The input clock signal CLK is provided to the data input terminal of flip-flop 70. Two internal signals, A and B, are provided to the data input terminals of flip-flops 71 and 72, respectively. As described in more detail below, on-chip oscilloscope circuit 100 is able to measure a signal skew between the internal signals A and B, or between the input clock signal CLK and the internal signals A and B. In the described embodiments, flip-flops 70-72 are designed to have the same trip point (TP). For example, assuming that the input clock signal CLK and the internal signals A and B transition between a low voltage of ground (0 Volts) and a high voltage of V_{CC}, then flip-flops 70-72 may be designed to have a trip point TP of about 0.5*V_{CC}. In other embodiments, the trip point TP may have other values.

Another internal signal C is applied to the data input terminals of flip-flops 73 and 74. In the described embodiment, the internal signal C has a relatively high slew rate. Flip-flop 73 is designed to have a first trip point TP1, and flip-flop 74 is designed to have a second trip point TP2, wherein TP1 is different than TP2. For example, assuming that the internal signal C transitions between a low voltage of ground (0 Volts) and a high voltage of V_{CC}, then flip-flop 73 may be designed to have a first trip point TP1 of about 0.25*V_{CC}, and flip-flop 74 may be designed to have a second trip point TP2 of about 0.75*V_{CC}. That is, flip-flop 73 will change states in response to an input signal that transitions across a voltage of 0.25*V_{CC}, and flip-flop 74 will change states in response to an input signal that transitions across a voltage of 0.75*V_{CC}. In other embodiments, the trip points TP1 and TP2 can be selected to have other values. In yet other embodiments, more than two flip-flops (each having a unique trip point) can be configured to receive the internal signal C.

In response to each rising edge of the test clock signal CLK_{OSC}, each of the flip-flops 70-74 latches (samples) the state of the applied input signal. The data samples latched in flip-flops 70-74 are provided to data storage block 110 as the signals CLK₀, A₀, B₀, C₁ and C₂, respectively. Although only five flip-flops 70-74 are included in the described examples, it is understood that other numbers of flip-flops can be used in other embodiments. For example, it is expected that about 50-60 flip-flops may be used to evaluate high speed signals that are generated by high speed circuitry (e.g., circuitry associated with a RAM, NVM, CPU or other similar device), which is located on the same chip as on-chip oscilloscope circuit 100.

Write operations to data storage block 110 are performed in response to the input clock signal CLK and an address value ADDR provided by counter circuitry 85. In one embodiment, counter circuitry 85 sequentially increments the address value ADDR in response to the input clock signal CLK, such that successive data sample values from flip-flops 70-74 are written to successive addresses within data storage block 110. The data sample values are subsequently read out from data storage block 110 to a serial/parallel interface, where the data sample values can be read externally (i.e., off-chip). More specifically, the serial/parallel interface converts parallel data read from data storage block 110 into serial data, which is transmitted off of the integrated circuit chip. As described in more detail below, these data sample values are used to evaluate various internal signals (e.g., internal signals CLK, A, B, and C) of the chip that includes on-chip oscilloscope circuit 100.

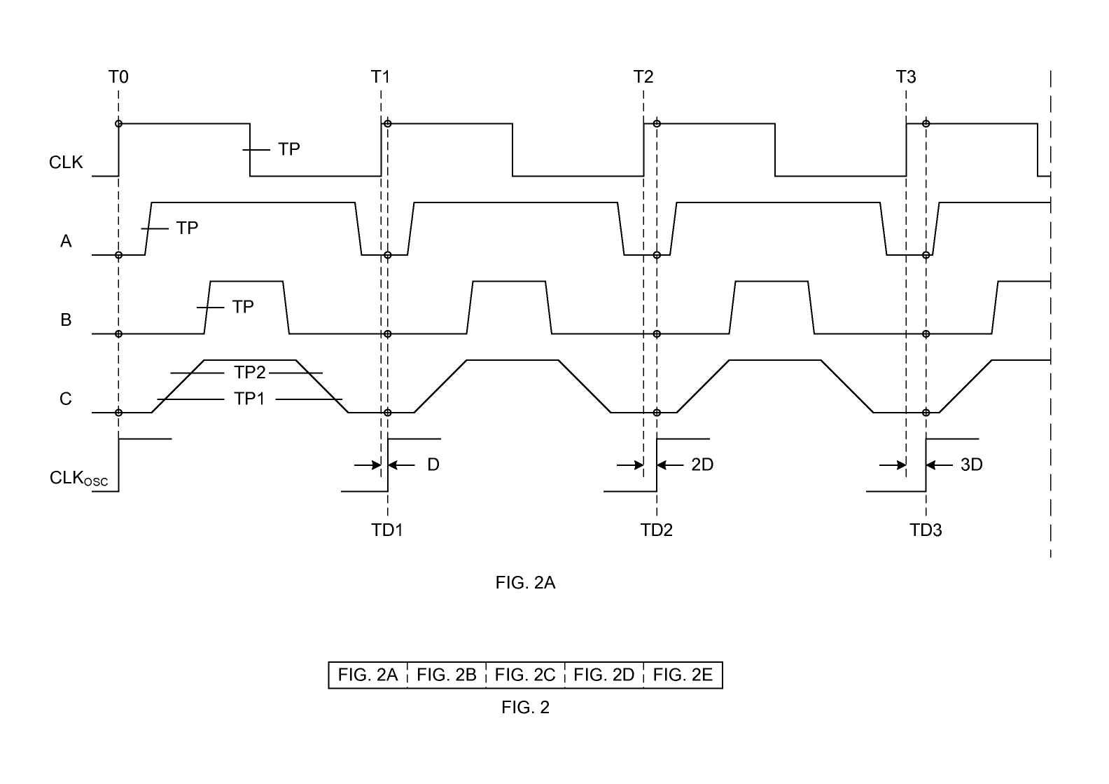

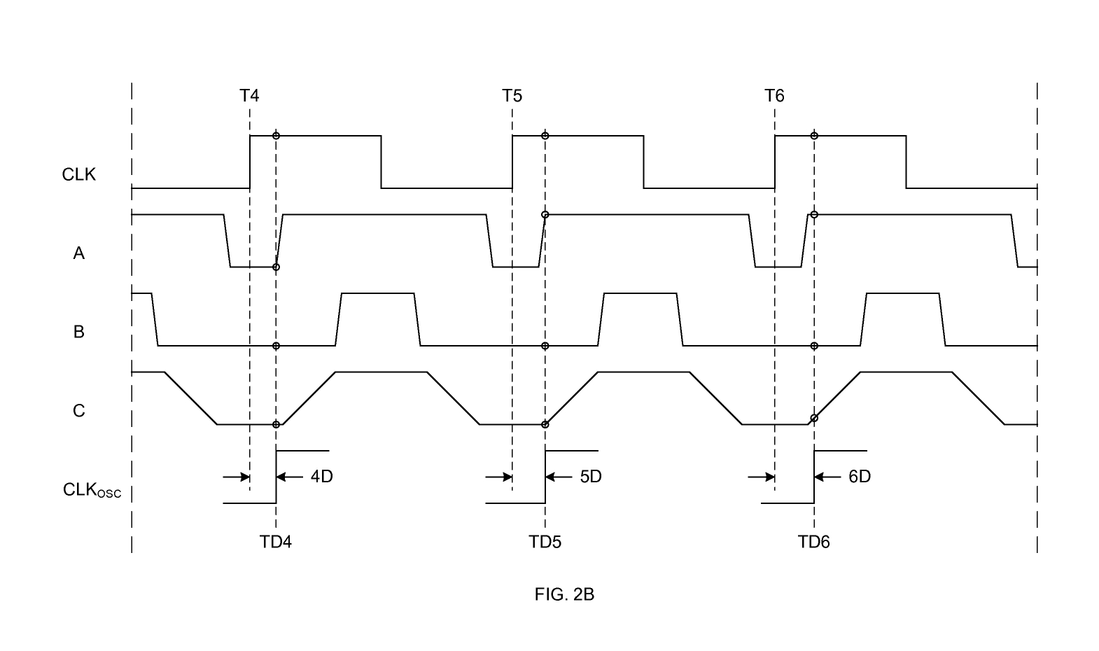

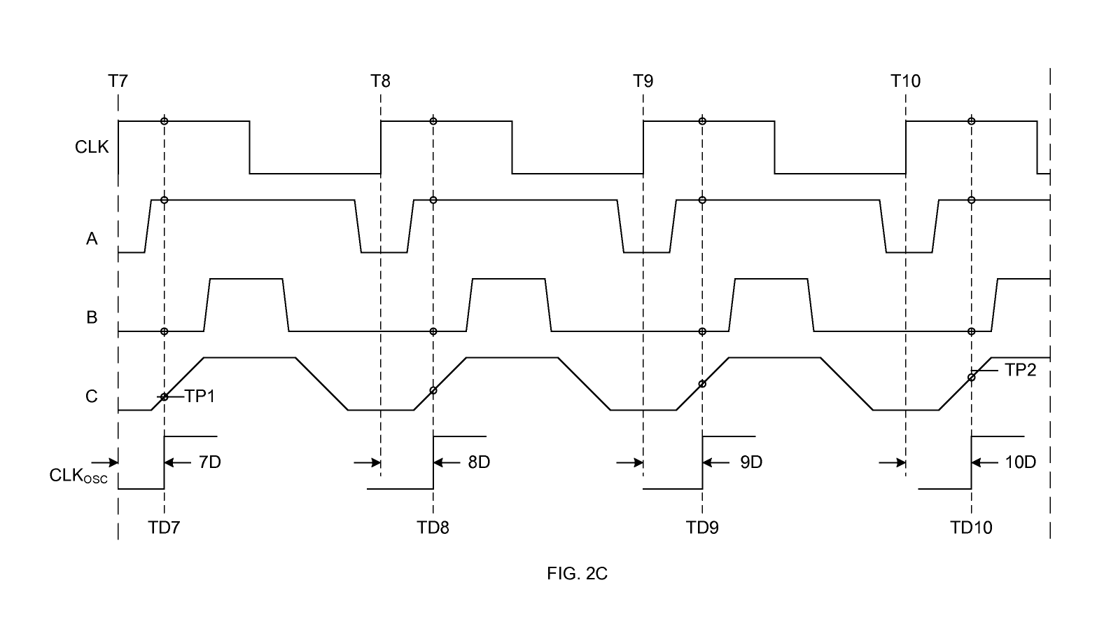

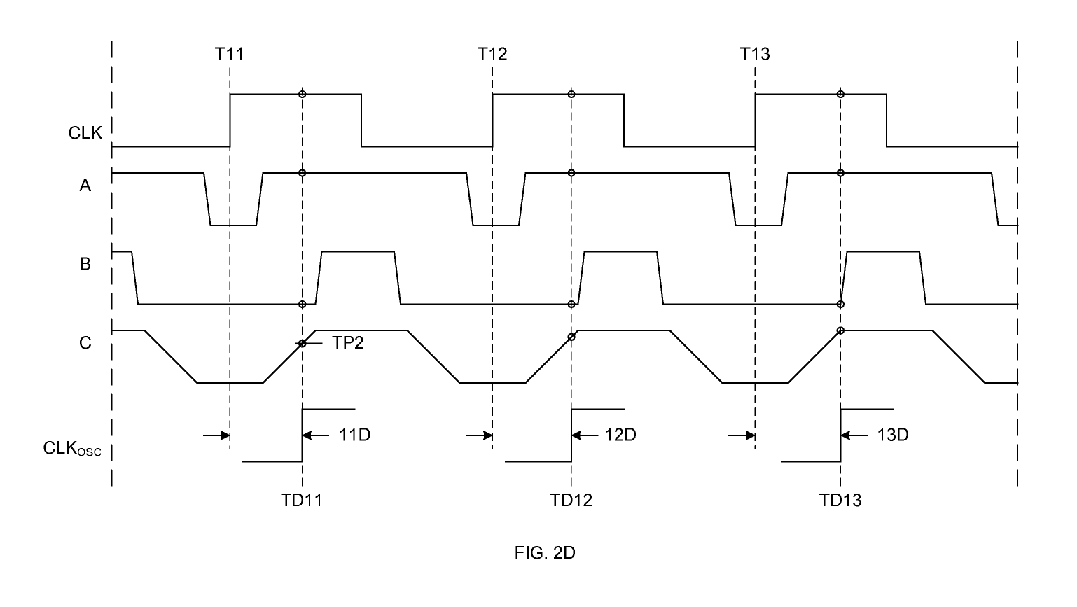

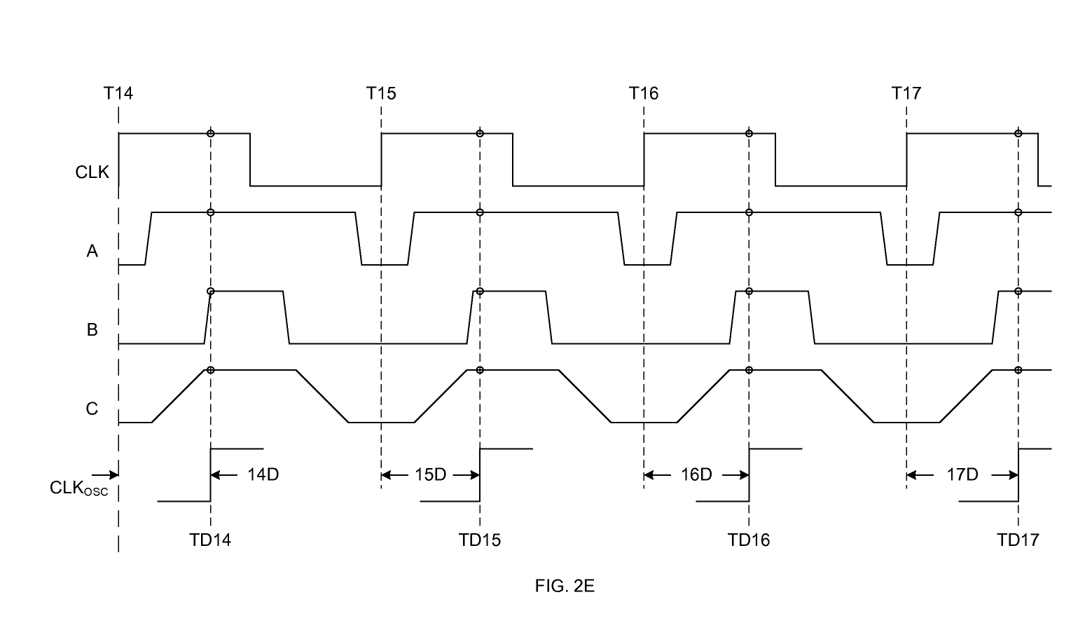

The operation of on-chip oscilloscope circuit 100 will now be described in more detail with respect to FIG. 2. FIG. 2, which includes FIGS. 2A-2E, illustrates the first 18 test cycles, which are used to evaluate the internal signals CLK, A, B and C, in accordance with one embodiment of the present invention.

Rising edges of the input clock signal CLK occur at times T0-T17, as illustrated by FIG. 2. In the described example, the input clock signal CLK has a frequency of 1 GHz, although other frequencies (e.g., up to 5 GHz) are possible in other embodiments. Also in the present example, each of the delay circuits D_{X} has a delay D equal to 20 picoseconds (although other delays are possible). The internal input signals A, B and C are periodic signals, which are asserted and de-asserted in an identical manner during each cycle of the input clock signal CLK. The internal signals A and B are relatively fast transitioning signals (e.g., column access signals, sense amplifier enable signals or logic signals of a memory circuit located on the integrated circuit chip), while the internal signal C has a relatively high slew rate (e.g., a word line signal of a memory circuit located on the integrated circuit chip). The trip points TP, TP1 and TP2 of flip-flops 70-74 are illustrated in FIG. 2.

FIG. 2 also illustrates the rising edges of the test clock signal CLK_{OSC}, which occur at times T0 and TD1-TD17. The generation of the test clock signal CLK_{OSC} will now be described in more detail. At the start of testing, flip-flops 70-74 are reset, and the counter 85 is reset to a count value CNT of zero and an address value ADDR of ‘A0’. In response to the count value CNT of zero, multiplexer 50 routes the input clock signal CLK as the test clock signal CLK_{OSC}. At time T0, the test clock signal CLK_{OSC} causes flip-flops 70-74 to latch (sample) the corresponding input signals (CLK, A, B, and C).

The data sample values are illustrated as small circles (‘o’) on the internal signals CLK, A, B and C in FIG. 2. Thus, at time T0, the data sample value CLK₀ has a value of ‘1’ (because the CLK signal exceeds the trip point TP), the data sample values A₀ and B₀ each has a value of ‘0’ (because the internal signals A and B are less than the trip point TP), the data sample value C₁ has a value of ‘0’ (because the internal signal C is less than the trip point TP1), and the data sample value C₂ has a value of ‘0’ (because the internal signal C is less than the trip point TP2).

The data latched in flip-flops 70-74 (i.e., the data sample values CLK₀, A₀, B₀, C₁ and C₂) are written to data storage block 110 in parallel, to an address specified by the address value ADDR. In the described example, data sampled at time T0 is written to address location ‘A0’ in data storage block 110. In the described example, the data storage block 110 operates in response to the input clock signal CLK, such that the data sampled at time T0 is written to address A0 of data storage block 110 in response to the rising edge of the input clock signal CLK at time T1. Counter circuitry 85 increments the address value ADDR each time that a set of sample data values are written to data storage block 110 (e.g., at each rising edge of the input clock signal CLK). For example, the counter circuitry 85 may increment the address value ADDR to the next address value ‘A1’ in response to the rising edge of the input clock signal CLK at time T1.

Each time that the input clock signal CLK transitions to a logic high state, the counter circuitry 85 also increments the counter value CNT. For example at time T1, the rising edge of the input clock signal CLK causes the counter value CNT provided to multiplexer 50 to increase to a value of ‘1’. At this time, the delayed clock signal CLK₁ is routed through multiplexer 50 as the test clock signal CLK_{OSC}.

As shown by FIG. 2A, the second rising edge of the test clock signal CLK_{OSC} occurs at time TD1. Note that at this time, the counter value CNT has been incremented, thereby causing the delayed clock signal CLK₁ to be routed as the test clock signal CLK_{OSC}. Flip-flops 70-74 sample the internal signals CLK, A, B and C at time TD1. In the illustrated example, the data values CLK₀, A₀, B₀, C₁ and C₂ sampled at time TD1 are the same as the data values CLK₀, A₀, B₀, C₁ and C₂ sampled at time T0. At time T2, data storage block 110 stores the newly sampled data values CLK₀, A₀, B₀, C₁ and C₂ (i.e., the data values sampled at time TD1) to the address location (A1) specified by the incremented address value ADDR.

Returning now to FIG. 2A, the third rising edge of the clock signal CLK occurring at time T2 increments the counter value CNT to a value of ‘2’, thereby causing the delayed clock signal CLK₂ to be routed as the test clock signal CLK_{OSC}. As a result, the third rising edge of the test clock signal CLK_{OSC} occurs at time TD2, or two delay periods 2*D after the rising edge of the clock signal CLK occurs at time T2. Flip-flops 70-74 sample the internal signals CLK, A, B and C at time TD2. In the illustrated example, the data values CLK₀, A₀, B₀, C₁ and C₂ sampled at time T1 are the same as the data values CLK₀, A₀, B₀, C₁ and C₂ sampled at times T0 and TD1. At time T3, data storage block 110 stores the newly sampled data values CLK₀, A₀, B₀, C₁ and C₂ (i.e., the data values sampled at time TD2) to the address location (A2) specified by the incremented address value ADDR.

This process continues, wherein during each successive cycle of the internal clock signal CLK, multiplexer 50 is controlled to route the next delayed clock signal in the series of delayed clock signals CLK, CLK_{N}. As illustrated by FIG. 2, the fourth through eighteenth rising edges of the test clock signal CLK_{OSC} occur at times TD3-TD17, respectively, (in response to the delayed clock signals CLK₃-CLK₁₇, respectively) wherein each successive rising edge of the test clock signal CLK_{OSC} is delayed by an additional delay period D. As a result, the flip-flops 70-74 effectively sample the internal signals CLK, A, B and C at slices having a resolution equal to the delay period D. If the input clock signal CLK has a frequency of 1 GHz (i.e., a clock cycle period of 1000 ps), then a delay period D of 20 ps allows 50 (1000/20) samples to be taken during a period of the input clock signal CLK. If the input clock signal CLK has a frequency of 5 GHz (i.e., a clock cycle period of 200 ps), then a delay period D of 10 ps would allow 20 (200/10) samples to be taken during a period of the input clock signal CLK.

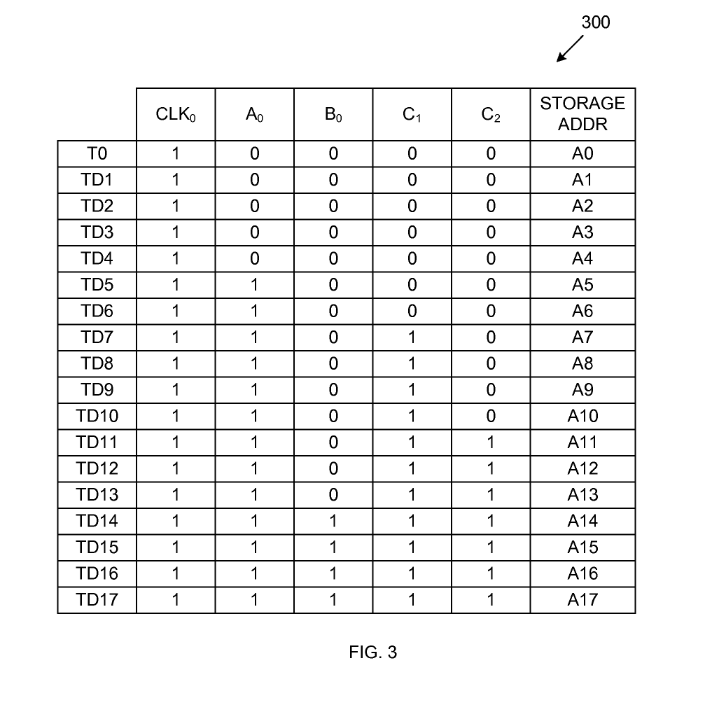

FIG. 3 is a table 300 that illustrates the data sample values CLK₀, A₀, B₀, C₁ and C₂ taken at times T0 and TD1-TD17, as well as the addresses to which these sample data values are written within data storage block 110, during the 18 test cycles illustrated by FIG. 2.

As illustrated by table 300 (and FIG. 2B), at time TD5, the internal signal A has a logic ‘1’ value, because the internal signal A exceeds the trip point value TP at this time. As a result, the data sample value A₀ taken at time TD5 has a logic ‘1’ value (representing a change from the previous logic ‘0’ data sample values recorded at times T0 and TD1-TD4). The internal signal A (and therefore the data sample value A₀) remains at a logic ‘1’ value for the duration of the illustrated sampling (i.e., TD5-TD17.)

As illustrated by table 300 (and FIG. 2C) at time TD7, the internal signal C has a voltage greater than the first trip point value TP1. As a result, the data sample value C₁ taken at time TD7 has a logic ‘1’ value (representing a change from the previous logic ‘0’ data sample values recorded at times T0 and TD1-TD6). The internal signal C (and therefore the data sample value C₁) remains at a logic ‘1’ value for the duration of the illustrated sampling (i.e., TD7-TD17).

As illustrated by table 300 (and FIG. 2D) at time TD11, the internal signal C has a voltage greater than the second trip point value TP2. As a result, the data sample value C₂ taken at time TD11 has a logic ‘1’ value (representing a change from the previous logic ‘0’ data sample values recorded at times T0 and TD1-TD10). The internal signal C (and therefore the data sample value C₂) remains at a logic ‘1’ value for the duration of the illustrated sampling (i.e., TD11-TD17).

As illustrated by table 300 (and FIG. 2E), at time TD14, the internal signal B has a logic ‘1’ value, because the internal signal B exceeds the trip point value TP at this time. As a result, the data sample value B₀ taken at time TD14 has a logic ‘1’ value (representing a change from the previous logic ‘0’ data sample values recorded at times T0 and TD1-TD13). The internal signal B (and therefore the data sample value B₀) remains at a logic ‘1’ value for the duration of the illustrated sampling (i.e., TD14-TD17.)

Each successive entry of data storage block 110 represents a sample of the periodic internal signals CLK, A, B and C, taken D time units apart. Thus, the entries of data storage block 110 represent the characteristics of the periodic internal signals CLK, A, B and C, themselves. The characteristics of the internal signals A, B and C can be identified by the entries stored in data storage block 110. For example, the entry for data sample value A₀ at address location A5 indicates that the internal signal A transitions to a logic high state at a time equal to 5*D (i.e., 5*20 ps=100 ps) after the rising edge of the internal clock signal CLK. Similarly, the entry for data sample value B₀ at address location A14 indicates that the internal signal B transitions to a logic high state a time equal to 14*D (i.e., 14*20 ps=280 ps) after the rising edge of the internal clock signal CLK. The time between the rising edges of the internal signals A and B can also be determined from the above-described entries (i.e., the skew between internal signals A and B is equal to 14*D−5*D=180 ps).

The slew rate of the internal signal C can also be determined from the contents of table 300, as two voltage levels of internal signal C are identified at two known times. More specifically, as illustrated by table 300 (and FIG. 2), the internal signal C has a voltage of about 0.25V_{CC} at time TD7, and a voltage of about 0.75V_{CC} at time TD11. Thus, the slope (slew rate) of the internal signal C can be determined dividing the increase in the internal signal C (i.e., 0.75V_{CC}−0.25V_{CC}=0.5V_{CC}) by the corresponding time period (i.e., 11*D−7*D=(11−7)*20 ps=80 ps).

Note that data regarding the downward transitions of the internal signals CLK, A, B and C, will be identified in a similar manner, as long as the sampling proceeds in the manner described above, until the total delay associated with the test clock signal CLK_{OSC} reaches the period of the input clock signal CLK (i.e., N*D=period of the input clock CLK).

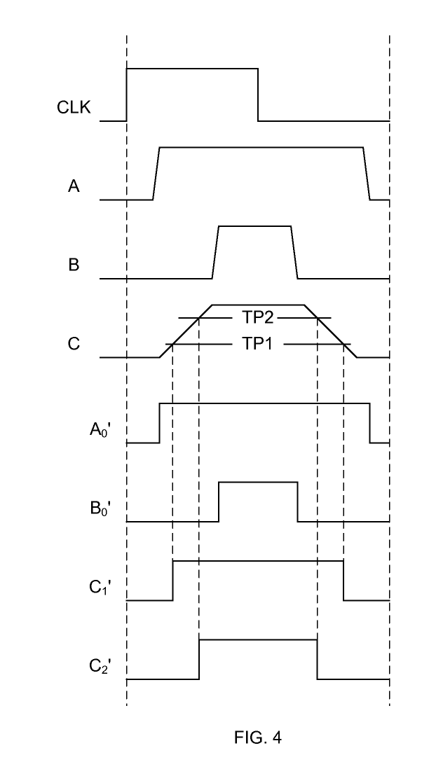

FIG. 4 is a waveform diagram that illustrates digital signals A₀′, B₀′, C₁′ and C₂′ that can be derived from the data sample values A₀, B₀, C₁ and C₂ taken in the manner described above in connection with FIGS. 1-3. The digital signals A₀′, B₀′, C₁′ and C₂′ of FIG. 4 illustrate the sampling across an entire period of the input clock signal CLK, such that downward transitions of the internal signals are also shown. It is important to note that the digital signals A₀′, B₀′, C₁′ and C₂′ may be generated off of the chip, in response to the data sample values read from data storage block 110. This advantageously allows the characteristics of the high-speed internal signals A, B and C to be viewed external to the chip.

In accordance with the description of the sampling provided above, it is understood that the time between the sampling of the data values and the time that the data values are written to data storage block 110 decreases as the sampling approaches the end of the period of the clock signal CLK. That is, as the delayed clock signal CLK routed through multiplexer 50 approaches the delayed clock signal CLK_{N}, a shorter period exists between the rising edge of the delayed clock signal CLK (i.e., the edge used to latch new data samples into flip-flops 70-74) and the subsequent rising edge of the input clock signal CLK (i.e., the edge used to write the contents of flip-flops 70-74 to data storage block 110). This issue can be handled as follows.

In one embodiment, sampling is performed only partially, but at least half way, through the period of the clock signal CLK. For example, sampling may be performed ¾ of the way through the period of the clock signal CLK. That is, sampling is stopped after the delayed clock signal CLK_{(3/4*N)} is routed through multiplexer 50. The results of this initial ¾ period sampling are stored in data storage block 110. Sufficient time exists between the time the samples are taken and the time that the samples are written to the data storage block 110. The clock signal CLK is then inverted, and the above described process is repeated, with sampling being performed only partially, but at least half way through, the period of the inverted clock signal. Again, sampling may be performed ¾ of the way through the period of the inverted clock signal CLK. That is, sampling is stopped after the delayed inverted clock signal CLK_{(3/4*N)} is routed through multiplexer 50. The results of this subsequent ¾ period sampling are stored in data storage block 110. The results of the initial and subsequent ¾ period samplings may be combined to create the waveforms for the entire period of the clock signal CLK. Valid samples would include those samples taken during the initial sampling run when the clock signal CLK had a logic ‘1’ value, and those samples taken during the subsequent sampling run when the inverted clock signal had a logic ‘1’ value.

In another embodiment, data sampling (and retiring the sampled data) is only performed during every other cycle of the clock signal CLK. For example, if the data signals A, B and C are sampled at time TD2, then the associated data sample values A₀, B₀, C₁ and C₂ stored in flip-flops 70-74 would not be written to the data storage block 110 until the rising edge of the clock signal CLK at time T4. In this example, the data signals A, B and C are not sampled between times T3 and T4. Also in this example, the counter value CNT and the address value ADDR are only incremented during even rising edges of the clock signal CLK (i.e., T2, T4, T6, etc.). Alternately, the counter value CNT and the address value ADDR could be incremented only during odd rising edges of the clock signal CLK (i.e., T1, T3, T5, etc.). These embodiments allow at least one full cycle of the clock signal CLK to retire the samples stored in flip-flops 70-74.

Advantages of the present invention include the following.

The sampling strobe (i.e., CLK_{OSC}) is developed completely internally (on-chip), and can be skewed with predetermined timing intervals of 10 picoseconds or more.

Multiple data sample values are provided through parallel outputs (e.g., from flip-flops 70-74) to on-chip storage (e.g., data storage block 110).

Periodic signals (e.g., internal signals A, B and C) are sampled at any frequency up to 5 GHz.

The same architecture (i.e., on-chip oscilloscope circuit 100) is applicable to different types of process technologies.

The user is able to identify faults and timing problems within the system under test (e.g., the circuit providing the internal signals A, B and C) in response to the data sample values read from on-chip storage (e.g., data storage block 110). In response, the user is able to debug the system under test.

After debugging the high-speed circuit under test (e.g., the circuit providing the internal signals A, B and C), the user is able to tune the internal signals so as to adjust the timing. This tuning can be performed by adjusting configuration bits on the chip that control the voltage and/or timing of the internal signals.

Although the present invention has been described in connection with specific embodiments, it is understood that modifications can be made to the described circuitry, without departing from the scope of the present invention. For example, the delay circuits D_{X} could be replaced with a conventional adjustable delay-locked loop (DLL) in other embodiments, thereby allowing the user to analyze the operation of the circuit at different time intervals. Moreover, the present invention could be modified to sample periodic internal signals which are not asserted/de-asserted every cycle of the input clock signal CLK, but rather, are asserted/de-asserted every other cycle (or every third, fourth, etc., cycle) of the input clock signal CLK. This modification would include incrementing the counter value CNT every other (or every third, fourth, etc.) cycle of the input clock signal, and only performing sampling during the cycles that the internal signals are asserted/de-asserted.

Although the invention has been described in connection with several embodiments, it is understood that this invention is not limited to the embodiments disclosed, but is capable of various modifications, which would be apparent to a person skilled in the art. Accordingly, the present invention is limited only by the following claims.

I claim:

1. An integrated circuit chip comprising:
a plurality of delay elements connected in series and coupled to receive an input clock signal, wherein each of the plurality of delay elements provides a corresponding delayed clock signal;
a multiplexer coupled to receive the input clock signal and the delayed clock signals provided by the delay elements;
a counter that provides a count value to a control input of the multiplexer, wherein the multiplexer routes the input clock signal or one of the delayed clock signals as a test clock signal in response to the count value;
a plurality of flip-flops, each having a clock input terminal coupled to receive the test clock signal, and an input terminal coupled to receive an internal signal of the integrated circuit chip to be tested; and
a memory block coupled to output terminals of the flip-flops.

2. The integrated circuit chip of claim 1, wherein each of the delay elements introduces the same delay to a received signal.

3. The integrated circuit chip of claim 2, wherein the input clock signal has a cycle period, and wherein the plurality of delay elements introduce a total delay of at least one half of the cycle period.

4. The integrated circuit chip of claim 3, wherein the plurality of delay elements introduce a total delay approximately equal to the cycle period.

5. The integrated circuit chip of claim 3, wherein each of the plurality of delay elements introduces a delay of about 1/50 of the cycle period.

6. The integrated circuit chip of claim 3, wherein the plurality of delay elements include at least about 20 delay elements.

7. The integrated circuit chip of claim 1, wherein the counter is coupled to receive the input clock signal, wherein the count value is incremented by the input clock signal.

8. The integrated circuit chip of claim 1, wherein the internal signals comprise signals used to access a memory located on the integrated circuit chip.

9. The integrated circuit chip of claim 1, wherein the memory block is coupled to receive the input clock signal, wherein data provided on the output terminals of the flip-flops is written to the memory block in response to the input clock signal.

10. The integrated circuit chip of claim 1, further comprising a parallel-to-serial interface coupled to the memory block, wherein data is transferred from the memory block to a location external to the integrated circuit chip through the parallel-to-serial interface.

11. The integrated circuit chip of claim 1, wherein the plurality of flip-flops include a first set of flip-flops having a first trip point, and a second set of flip-flops having a second trip point, different than the first trip point.

12. The integrated circuit chip of claim 1, wherein a first one of the internal signals is applied to an input terminal of a flip-flop in the first set of flip-flops, and also to an input terminal of a flip-flop in the second set of flip-flops.

13. The integrated circuit chip of claim 1, wherein one of the internal signals is the input clock signal.

14. A method comprising:
generating a signal to be characterized on an integrated circuit chip, wherein the signal has an identical pattern during each of a plurality of cycles of an input clock signal;
sampling the signal on the integrated circuit chip with successively delayed versions of the input clock signal, thereby generating a plurality of data samples that represent the pattern of the signal over a cycle of the input clock signal;
storing the data samples in a memory block of the integrated circuit chip; and
transferring the data samples from the memory block to a location external to the integrated circuit chip.

15. The method of claim 14, further comprising generating the successively delayed version of the input clock signal by applying the input clock signal to a plurality of identical series-connected delay elements.

16. The method of claim 14, wherein the signal is a memory access signal used to access a memory of the integrated circuit chip during normal operation of the integrated circuit chip.

17. The method of claim 14, further comprising sampling the signal with two flip-flops having two different trip points.

18. The method of claim 17, further comprising identifying a slew rate of the signal in response to the data samples.

19. The method of claim 14, further comprising storing the data samples in the memory block in response to the input clock signal.

20. The method of claim 14, wherein the step of transferring the data samples from the memory block to a location external to the integrated circuit chip comprises serializing the data samples.
